(19) United States
(12) Patent Application Publication
(10) Pub. No.: US 2018/0160562 A1
(43) Pub. Date: Jun. 7, 2018

(54) SIDE PLATE MOUNTING APPARATUS AND CASE USING THE SAME

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: YUE LIU, Wuhan (CN); SHUAN-PING YAN, Wuhan (CN); YUAN-GANG SHU, Wuhan (CN); LING-XIN ZENG, Wuhan (CN); XIAO-ZHONG JING, Wuhan (CN); YI-SHENG LIN, New Taipei (TW); CHUNG CHAI, New Taipei (TW); LIANG-CHIN WANG, New Taipei (TW)

(21) Appl. No.: 15/482,999

(22) Filed: Apr. 10, 2017

(30) Foreign Application Priority Data
Dec. 2, 2016 (CN) 201611099812.1

(51) Int. Cl. H05K 7/14; E05C 1/08; E05C 19/10

(52) U.S. Cl. CPC H05K 7/1487; E05C 19/10; E05C 1/08

(57) ABSTRACT

A mounting apparatus for a side plate to enable the side plate to be mounted to a case includes a sliding member, an elastic member, and at least one hook defined on the side plate. The sliding member is slidably mounted to an inner surface of the side plate. An end of the sliding member is connected to a side of the side plate by the elastic member, each of the sliding member and the side plate defines a latching slot corresponding to the hook. The sliding member is slidable on the side plate to lock or release the hook. A case using the mounting apparatus and the side plate is further disclosed.

### FIELD

The subject matter herein generally relates to a mounting apparatus for side plate and a case using the mounting apparatus and the side plate.

### BACKGROUND

A side plate is secured to a computer or server case. Typically, the case includes two substantially parallel side plates. Each of the two side plates defines a plurality of through holes. The side plate defines a plurality of screw holes. In assembly, a plurality of screws extends through the plurality of through holes and is screwed into the plurality of screw holes, thereby securing the side plates onto the case. In disassembly of the side plate, the plurality of screws can be removed by a screwdriver. A mounting apparatus that can be tool-free to secure a side plate to a case would be beneficial.

### BRIEF DESCRIPTION OF THE DRAWINGS

Implementations of the present technology will now be described, by way of example only, with reference to the attached figures.

FIG. 1 is an isometric view of an exemplary embodiment of a mounting apparatus for a side plate mountable on a case.

FIG. 2 is an isometric view of the mounting apparatus of FIG. 1.

FIG. 3 is an exploded view of the mounting apparatus of FIG. 2.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the exemplary embodiments described herein.

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series and the like.

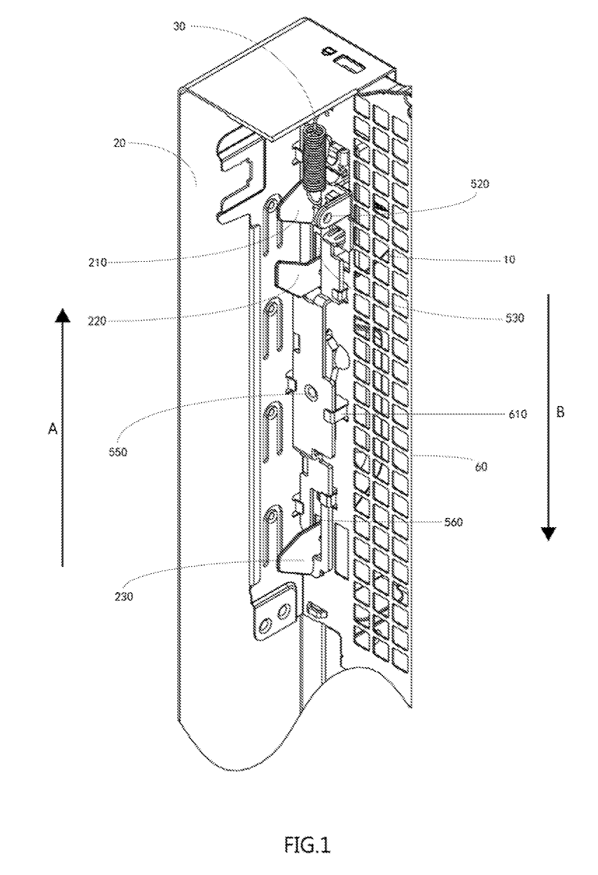

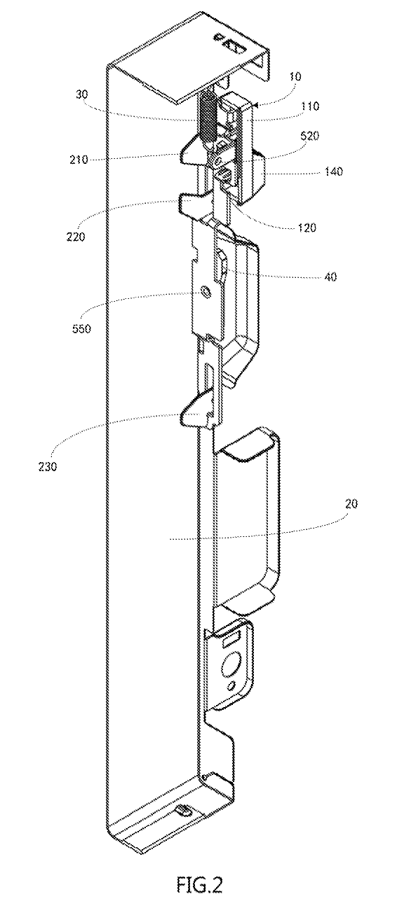

FIGS. 1 to 3 illustrate a mounting apparatus (not labeled) for a side plate 20 in an exemplary embodiment. The mounting apparatus is used to mount the side plate 20 to a case 60.

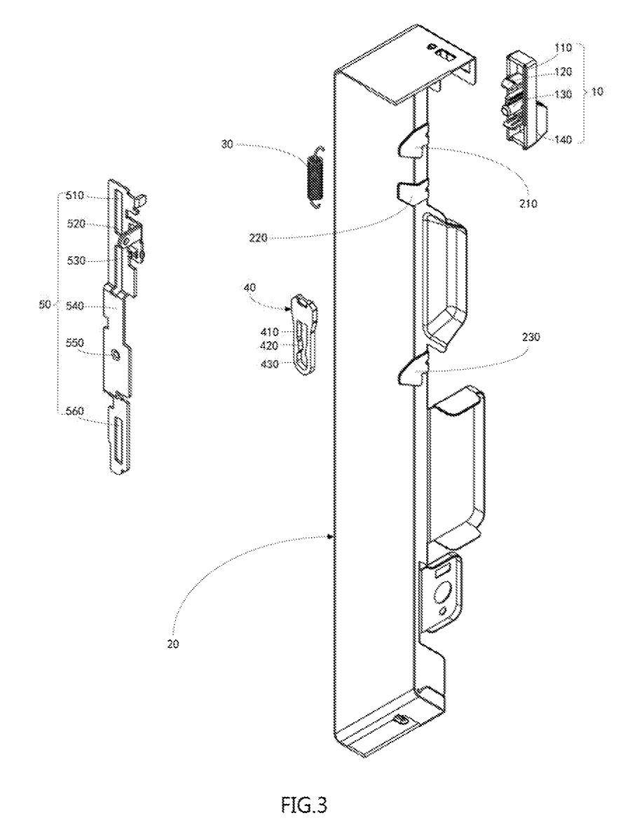

In the exemplary embodiment, as shown in FIG. 3, the mounting apparatus can include a sliding member 50, an elastic member 30, and at least one hook defined on the side plate 20. The elastic member 30 can be a spring with hooked ends (hook spring). The sliding member 50 is slidably mounted to an inner surface of the side plate 20. The sliding member 50 can include a sliding board 540, the sliding board 540 can be rectangular. A plurality of engagement portions 610 (see FIG. 1) can be defined on an inner surface of the case 60, the sliding board 540 can be slidably mounted to the inner surface of the case 60 through the plurality of engagement portions 610. An end of the sliding member 50 is connected to an end of the case 60 by the elastic member 30.

Each of the sliding member 50 and the side plate 20 defines a latching slot corresponding to the hook, the sliding member 50 is slidable on the side plate 20 to lock or release the hook.

In at least one exemplary embodiment, the sliding member 50 includes two opposing ends. A first latching slot 510 is defined on one of the two ends, a second latching slot 560 is defined on the other one of the two ends. The first latching slot 510 and the second latching slot 560 extend along a movement direction of the sliding member 50. The side plate 20 includes a first hook 210 that couples with the first latching slot 510 and a second hook 230 that couples with the second latching slot 560.

The elastic member 30 is parallel with the sliding direction of the sliding member 50. When the first hook 210 passes through the first latching slot 510 and the second hook 230 passes through the second latching slot 560, the elastic member 30 keeps the sliding member 50 in a first position where the first latching slot 510 locks the first hook 210 and the second latching slot 560 locks the second hook 230 under tension force of the elastic member 30.

When the sliding member 50 is driven to move along a first direction A to a second position under external force, the first latching slot 510 and the second latching slot 560 are moved along with the sliding member 50 to a second position. At the second position, the first latching slot 510 releases the first hook 210 and the second latching slot 560 releases the second hook 230, the elastic member is elastically deformed. When external force is released, the elastic member 30 retracts along a second direction B, the second direction being opposite to the first direction. The sliding member is thereby moved back to the first position.

The first hook 210 and the second hook 230 extend along a same direction. When the first latching slot 510 and the second latching slot 560 move along with the sliding member 50, the first hook 210 and the second hook 230 can be locked or released at same time. When the first hook 210 and the second hook 230 are locked by the first latching slot 510 and the second latching slot 560, the side plate 20 is firmly secured to the case 60.

The mounting apparatus can include a clamp 40. The clamp 40 is mounted to the case 60. An end of the clamp 40 defines a locking hole 430. The sliding member 50 includes a location post 550 that couples with the locking hole 430. When the sliding member 50 slides to the second position, the location post 550 is stuck in the locking hole 430 to hold the sliding member 50 so that the side plate 20 can be removed from the case 60.

The clamp 40 can be made of elastic material. The other end of the clamp 40 defines a sliding slot 410, a skewed slot 420 can be further defined on the clamp 40 to connect the sliding slot 410 and the locking hole 430. When the sliding member 50 slides towards the second position, the location post 550 slides to the locking hole 430 along the sliding slot 410 and the skewed slot 420.

The mounting apparatus can further include a locking member 10. The locking member 10 is slidably mounted to an outer surface of the side plate 20 and fixed to the sliding member 50. The locking member 10 includes a locking bar 110 and a pushing member 140 defined on the locking bar 110. The locking bar 110 is fixed to the sliding member 50 with a connecting member (not labeled), and the case 60 defines a sliding groove (not shown) corresponding to the connecting member.

The connecting member includes at least two elastic locking toggles 120 defined on opposing ends of the locking bar 110 and a pushing post 130 defined in the middle of the locking bar 110. The sliding member 50 defines latching holes (not shown) corresponding to the at least two elastic locking toggles 120 and a clamping hole (not labeled) corresponding to the pushing post 130.

The mounting apparatus can further include a leading member 220 defined on the side plate 20. The leading member 220 defines a leading slant (not labeled), and the sliding member 50 defines a retracting slot 530. The leading member 220 passes through the retracting slot 530 and an end of the retracting slot 530 abuts the leading slant. The leading member 220 can be a leading plate, the retracting slot 530 can be an elongated slot.

The embodiments shown and described above are only examples. Even though numerous characteristics and advantages of the present technology have been set forth in the foregoing description, together with details of the structure and function of the present disclosure, the disclosure is illustrative only, and changes may be made in the details, including matters of shape, size, and arrangement of the parts within the principles of the present disclosure, up to and including the full extent established by the broad general meaning of the terms used in the claims.

What is claimed is:

1. A mounting apparatus for a side plate, the mounting apparatus comprising:
a sliding member slidably mounted to an inner surface of the side plate;
an elastic member; and
at least one hook defined on the side plate;
wherein an end of the sliding member is connected to a side of the side plate by the elastic member, each of the sliding member and each of the side plate define a latching slot corresponding to the hook, the sliding member is slidable on the side plate to lock or release the hook.

2. The mounting apparatus of claim 1, wherein the elastic member is a hook spring, the hook spring is parallel with a sliding direction of the sliding member, when the hook passes through the latching slot, the elastic member drives the sliding member to lock the hook by pretension force.

3. The mounting apparatus of claim 1, wherein the mounting apparatus further comprises a clamp, the clamp is mounted to the chassis, an end of the clamp defines a locking hole, the sliding member further comprises a location post coupling with the locking hole; when the sliding member slide to a released position, where the sliding member releases the hook, the location post maintains in the locking hole to hold the sliding member.

4. The mounting apparatus of claim 3, wherein the clamp is made of elastic material, another end of the clamp defines a sliding slot, a skewed slot is further defined on the clamp to connect the sliding slot and the locking hole; when the sliding member slides towards a locking position, where the sliding member locks the hook, the location post slides to the locking hole along the sliding slot and the skewed slot.

5. The mounting apparatus of claim 1, wherein the mounting apparatus further comprises a locking member, the locking member is slidably mounted to an outer surface of the side plate and fixed to the sliding member.

6. The mounting apparatus of claim 5, wherein the locking member comprises a locking bar and a pushing member defined on the locking bar, the locking bar is fixed to the sliding member with a connecting member, the side plate defines a sliding groove corresponding to the connecting member.

7. The mounting apparatus of claim 5, wherein the connecting member comprises at least two elastic locking toggles defined on two opposing ends of the locking bar and a pushing post defined in a middle portion of the locking bar; the sliding member defines a plurality of latching holes corresponding to the at least two elastic locking toggles and a clamping hole corresponding to the pushing post.

8. The mounting apparatus of claim 1, wherein the mounting apparatus further comprises a leading member defined on the side plate, the leading member defines a leading slant, the sliding member defines a retracting slot, the leading member pass through the retracting slot; and wherein an end of the retracting slot abuts the leading slant.

9. The mounting apparatus of claim 8, wherein the leading member is a leading plate, the retracting slot is an elongated slot.

10. The mounting apparatus of claim 1, wherein the sliding member defines a first latching slot and a second latching slot on two opposing ends of the sliding member, the first latching slot and the second latching slot extend along the sliding direction of the sliding member, the side plate defines a first hook corresponding to the first latching slot and a second hook corresponding to the second latching slot.

11. A case comprising:
a side plate;
a sliding member slidably mounted to an inner surface of the side plate;
an elastic member; and
at least one hook defined on the side plate;
wherein an end of the sliding member is connected to a side of the side plate by the elastic member, each of the sliding member and each of the side plate define a latching slot corresponding to the hook, the sliding member is slidable on the side plate to lock or release the hook.

12. The case of claim 11, wherein the elastic member is a hook spring, the hook spring is parallel with a sliding direction of the sliding member, when the hook passed through the latching slot, the hook spring drives the sliding member to lock the hook by pretension force.

13. The case of claim 11, wherein the case further comprises a clamp, the clamp is mounted to the chassis, an end of the clamp defines a locking hole, the sliding member further comprises a location post coupling with the locking hole; when the sliding member slide to a released position, where the sliding member releases the hook, the location post is stuck in the locking hole to hold the sliding member.

14. The case of claim 13, wherein the clamp is made of elastic material, another end of the clamp defines a sliding slot, a skewed slot is further defined on the clamp to connect the sliding slot and the locking hole; when the sliding member slides towards the locking position, where the sliding member locks the hook, the location post slides to the locking hole along the sliding slot and the skewed slot.

15. The case of claim 11, wherein the case further comprises a locking member, the locking member is slidably mounted to an outer surface of the side plate and fixed to the sliding member.

16. The case of claim 15, wherein the locking member comprises a locking bar and a pushing member defined on the locking bar, the locking bar is fixed to the sliding member with a connecting member, the side plate defines a sliding groove corresponding to the connecting member.

17. The case of claim 15, wherein the connecting member comprises at least two elastic locking toggles defined on two opposing ends of the locking bar and a pushing post defined in a middle portion of the locking bar; the sliding member defines a plurality of latching holes corresponding to the at least two elastic locking toggles and a clamping hole corresponding to the pushing post.

18. The case of claim 11, wherein the case further comprises a leading member defined on the side plate, the leading member defines a leading slant, the sliding member defines a retracting slot, the leading member pass through the retracting slot and an end of the retracting slot abuts the leading slant.

19. The case of claim 18, wherein the leading member is a leading plate, the retracting slot is an elongated slot.

20. The case of claim 11, wherein the sliding member defines a first latching slot and a second latching slot on two opposing ends of the sliding member, the first latching slot and the second latching slot extend along the sliding direction of the sliding member, the side plate defines a first hook corresponding to the first latching slot and a second hook corresponding to the second latching slot.
